(19) United States
(12) Patent Application Publication
(10) Pub. No.: US 2026/0243832 A1
(43) Pub. Date: Aug. 20, 2026

(54) Method for the joint estimation of internal resistance and SOC of lithium-ion batteries based on a fuzzy-empowered PI observer

(71) Applicant: CHONGQING University, Chongqing (CN)

(72) Inventors: Xiaosong Hu, Chongqing (CN); Jia Liu, Chongqing (CN); Kai Zhang, Chongqing (CN); Jiacheng Li, Chongqing (CN); Saeed Muhammad, Chongqing (CN); Wenxue Liu, Chongqing (CN); Hongao Liu, Chongqing (CN); Jinwen Li, Chongqing (CN)

(21) Appl. No.: 19/412,871

(22) Filed: Dec. 9, 2025

(30) Foreign Application Priority Data
Feb. 20, 2025 (CN) CN202510188964.1

(51) Int. Cl. G01R 31/367; G01R 31/387; G01R 31/389

(52) U.S. Cl. CPC G01R 31/367; G01R 31/387; G01R 31/389

(57) ABSTRACT

This invention presents a joint estimation method for internal resistance and state of charge (SOC) of lithium-ion batteries based on a fuzzy-empowered extended proportional-integral (PI) observer, which belongs to the field of battery technology. The method includes the following steps: S1: Designing an appropriate extended PI observer to transform the battery internal resistance into an augmented state, enabling joint estimation of the internal resistance and SOC; S2: Developing an intelligent strategy guided by information fusion and fuzzy logic. Based on the extended PI observer designed in Step S1, employing the low-density outlier detection (LOD) method combined with knowledge-based fuzzy logic to detect model uncertainties in real time; S3: According to predefined rules, modifying the control logic and adjusting battery internal polarization to achieve timely compensation for modeling deviations, thereby ensuring accurate SOC estimation.

### CROSS REFERENCE INFORMATION

This applicant claims benefit to the following priority application, Chinese Nonprovisional Patent Application Serial No. CN202510188964.1, filed on Feb. 20, 2025, which is incorporated herein in its entirety.

### FIELD OF INVENTION

This invention belongs to the field of battery technology and proposes a method for the joint estimation of internal resistance and SOC of lithium-ion batteries based on a fuzzy-empowered PI observer.

### BACKGROUND ART

The SOC of a battery is one of the most critical states in BMS, as most management and control decisions rely on its value. Inaccurate estimation of battery SOC can easily lead to overcharging or over-discharging, reduced battery balancing capability, capacity decay, and even permanent damage. Therefore, accurate estimation of battery SOC is essential for the safe, reliable, and long-life operation of the battery system.

SOC estimation is primarily divided into the direct calculation based on ampere-hour integration, the methods based on electrochemical models (EMs), the methods based on equivalent circuit models (ECMs), and data-driven methods. In practical applications, the direct calculation method suffers from uncertainties in parameter measurements, resulting in limited accuracy. The EM-based methods have disadvantages such as model complexity, overfitting, and high computational cost. The data-driven methods require a large amount of high-quality training data and are prone to overfitting. Given this, only the ECM-based estimation methods are highly feasible and have significant application potential due to their lower complexity, satisfactory accuracy, and robustness. However, ECMs are highly sensitive to battery parameters, which brings the idea of developing the joint estimation methods. Current joint estimation approaches mainly combine recursive least squares (RLS) with Kalman filters and their variants to perform parameter identification and SOC co-estimation. These methods still have certain limitations, such as assuming unrealistic Gaussian noise and poor robustness under random operating scenarios. Moreover, due to the limited accuracy of ECMs, they cannot capture the genuine electrochemical response under highly dynamic conditions, causing model deviations that are mistakenly interpreted as one part of the internal resistance. This method adversely affects SOC estimation accuracy. In existing research, uncertainties caused by different parameters are generally treated equally, without specific attention to the physical meaning of each battery parameter, and the individual impact of each parameter on the output and estimation accuracy is also largely neglected.

### SUMMARY OF THE INVENTION

In view of the above, the purpose of this invention is to provide a method for the joint estimation of internal resistance and SOC of lithium-ion batteries based on a fuzzy-empowered PI observer. The proposed method employs an extended PI observer to transform the internal resistance into an augmented state, and integrates LOD with fuzzy logic to perform real-time detection and compensation of model defects. This approach effectively ensures an adaptive control mechanism capable of perceiving model uncertainties, thereby achieving high-accuracy and high-robustness estimation of internal resistance and SOC.

To achieve the above objective, the present invention provides the following technical solution:

A method for the joint estimation of internal resistance and SOC of lithium-ion batteries based on a fuzzy-empowered PI observer, comprising the following steps:
S1: Designing an appropriate extended PI observer to transform the internal resistance of the lithium-ion battery into an augmented state, so as to jointly estimate the internal resistance and the SOC.
S2: Developing an intelligent strategy empowered by incorporating information fusion and fuzzy logic. Based on the extended PI observer designed in Step S1, the method employs the concept of low-density outlier detection (LOD), combined with knowledge-based fuzzy logic, to detect model uncertainty in real time.
S3: According to predefined rules, modifying the control logic and adjusting the internal polarization of the battery to achieve timely compensation for modeling defects, thereby ensuring accurate SOC estimation.

Furthermore, in Step S1, the selected extended PI observer is as follows:

$$\{ \begin{matrix}\tilde{x} = A \tilde{x} + Bu + {K}_{p} ( y - \tilde{y} ) + {K}_{i} {S}_{e} \\ {\dot{S}}_{e} = {K}_{f i} ( y - \tilde{y} ) \\ \tilde{y} = h ( x ) + D u\end{matrix}$$

where Kₚ and Kᵢ are the proportional and integral gain matrices, Sₑ is the K_{ft} times the integration of error.

Furthermore, Step S2 specifically comprises the following steps:
S21: For each measured data, calculating the relative outlier-ness of selected variables. A value closer or larger than 1 indicates a high fluctuation.
S22: The relative outlier-ness values are input into the fuzzy logic system, which classifies them into three levels: low, medium, and high. In addition, the input describing the current system state is also fed back into the fuzzy system.
S23: The fuzzy logic system makes a decision, which can be classified into normal, normal compensation, and model uncertainty scenarios.

Furthermore, in step S22, the fuzzy logic process comprises three steps: fuzzification, rule formulation, and defuzzification. The fuzzy logic model defines a set of rules, and each fuzzy rule is expressed in the form of an IF-THEN condition.

Furthermore, in Step S2, the extended PI observer is described by the following expression:

$$\{ \begin{matrix}{\hat{x}}_{e o} = {A}_{e o} {\hat{x}}_{e o} + {B}_{e o} u + {K}_{{p}_{eo}} ( y - \hat{y} ) + {K}_{i {2}_{eo}} {S}_{e} \\ {\dot{S}}_{e} = {K}_{i {1}_{eo}} ( y - \hat{y} ) \\ \hat{y} = {h}_{e o} ( {\hat{x}}_{e o} , u )\end{matrix}$$

$$where$$

$${x}_{e o} = {[ {V}_{1} {V}_{2} soc {R}_{in} ]}^{T}$$

$${A}_{e o} = [ \begin{matrix}- 1 / {R}_{1} {C}_{1} & 0 & 0 & 0 \\ 0 & - 1 / {R}_{2} {C}_{2} & 0 & 0 \\ 0 & 0 & 0 & 0 \\ 0 & 0 & 0 & 0\end{matrix} ] ; {B}_{e o} = [ \begin{matrix}1 / {C}_{1} \\ 1 / {C}_{2} \\ {η}_{i} / {C}_{t} \\ 0\end{matrix} ]$$

$${h}_{e o} ( {\hat{x}}_{e o} , u ) = {∇}_{o c} ( s \hat{o} c ) + {\hat{V}}_{1} + {\hat{V}}_{2} + {\hat{R}}_{in} I$$

$${K}_{{p}_{eo}} = {[ {K}_{p {1}_{eo}} {K}_{p {2}_{eo}} {K}_{p {3}_{eo}} {K}_{p {4}_{eo}} ]}^{T}$$

$${K}_{{i}_{eo}} = {[ {K}_{i {1}_{eo}} {K}_{i {2}_{eo}} {K}_{i {3}_{eo}} {K}_{i {4}_{eo}} ]}^{T}$$

where Kₚₑₒ and Kᵢₑₒ are the proportional and integral gain matrices, respectively.

Furthermore, in Step S3, upon confirmation of model uncertainty, the control logic is adaptively adjusted according to a set of predefined rules to regulate the internal polarization of the battery, thereby mitigating the effects of modeling defects, and continuing until the system returns to a normal state and the cumulative error recovers to its previous value. The approach for correcting modeling defects is given as follow:

Whenever the model-based output ex exhibits fluctuations exceeding a predetermined threshold, its score is observed, and similar trends are searched among the scores of sôcₖ, Icrₖ and dVocₖ₋₁. Upon confirmation of model uncertainty, adjusting the internal polarization of the battery, until the system returns to a normal state and the cumulative error recovers to its previous value.

The beneficial effects of the invention are summarized below:
(1) The proposed method takes into account modeling uncertainties and is capable of reflecting more genuine electrochemical response of the battery under highly dynamic conditions. The proposed joint estimation method of internal resistance and SOC achieves higher accuracy and robustness, with efficient computation and great potential for practical applications.
(2) The proposed method integrates an intelligent strategy that combines information fusion and fuzzy logic-based real-time detection of model defects with an extended PI observer. This enables real-time detection and compensation of model deficiencies while explicitly interpreting the physical meaning of each battery parameter and clarifying their specific impacts on model outputs and estimation accuracy.

Other advantages, objectives, and features of the present invention will be set forth in part in the following description and, in part, will become apparent to those skilled in the art upon examination of the following, or may be learned through the practice of the present invention. The objectives and other advantages of the invention may be realized and attained by means of the instrumentalities and combinations particularly pointed out in the appended description.

### DESCRIPTION OF THE DRAWINGS

To more clearly illustrate the objectives, technical solutions, and advantages of the present invention, the following provides a detailed description of preferred embodiments in conjunction with the accompanying drawings, in which:

FIG. 1 illustrates a schematic diagram of the joint estimation method for battery internal resistance and SOC in this invention.

FIG. 2 illustrates an overall flowchart of this invention.

FIG. 3 illustrates a schematic diagram of a second-order equivalent circuit model of the battery in this invention.

FIG. 4 illustrates a detailed flowchart of Step S1 in an embodiment of this invention.

FIG. 5 illustrates a detailed flowchart of Step S12 in an embodiment of this invention.

FIG. 6 illustrates a detailed flowchart of Step S3 in an embodiment of this invention.

FIG. 7 illustrates the parameters of the fuzzy logic model used in Step S3 in an embodiment of this invention.

### DETAILED DESCRIPTION OF THE INVENTION

The following specific examples are provided to illustrate the embodiments of this invention. Those skilled in the art can readily understand other advantages and effects of the invention based on the disclosure of this specification. This invention may also be implemented or applied in various alternative embodiments, and the details described herein may be modified or altered in various ways without departing from the spirit of the invention, depending on different perspectives and applications. It should be noted that the drawings provided in the following embodiments are merely schematic illustrations of the basic concept of the invention. Where there is no conflict, the embodiments and the features described therein may be combined with one another.

It should be noted that the drawings provided in the following embodiments are merely schematic illustrations used to explain the basic concept of this invention. Therefore, only components relevant to the invention are shown in the figures, and they are not drawn according to the actual number, shape, or dimensions used in implementation. In practice, the form, quantity, and proportion of the components may be altered as desired, and the layout of the components may be more complex.

In the following description, numerous details are set forth to provide a more thorough understanding of the embodiments of this invention. However, it will be apparent to those skilled in the art that the embodiments of the invention may be implemented without these specific details. In other embodiments, well-known structures and devices are shown in the form of block diagrams rather than in detail, so as not to obscure the embodiments of this invention.

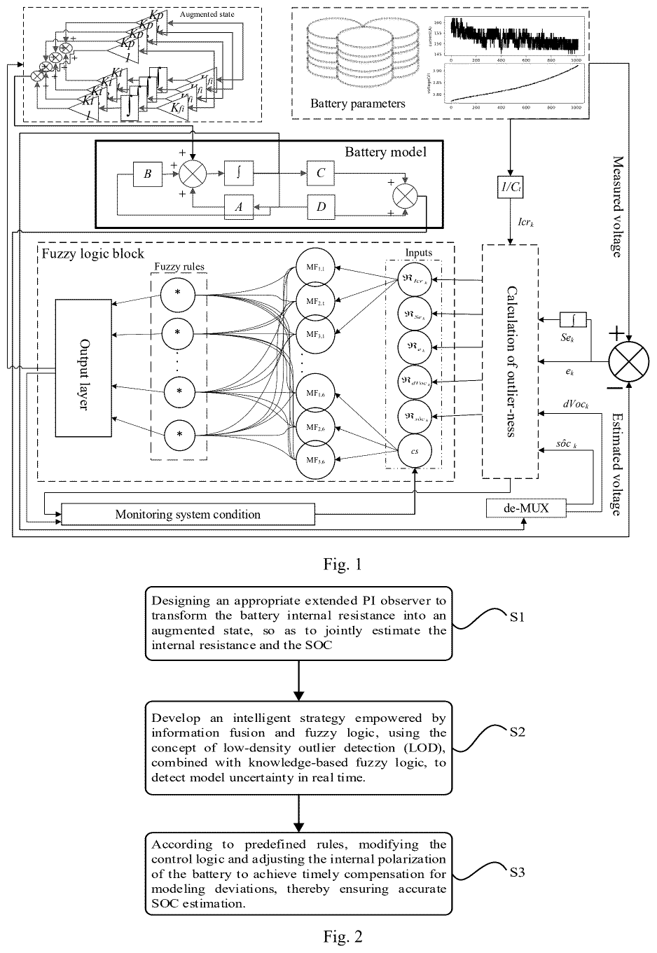

Referring to FIG. 1 and FIG. 2, a method for the joint estimation of internal resistance and SOC of a lithium-ion battery based on a fuzzy-empowered PI observer, comprising the following steps:

S1: Performing parameter sensitivity analysis based on a second-order RC ECM and the OCV-SOC mapping relationship, so as to analyze the variation of estimation performance of the battery model under different parameter and external conditions and reveal that the internal resistance is the dominant parameter affecting the accuracy of battery state estimation.

Referring to FIG. 3, in Step S1, the battery model is a second-order RC ECM, which has a SOC-dependent OCV. According to Kirchhoff's principle, the dynamics of the charge-transfer process can be represented as:

$$I = {I}_{{R}_{1}} + {I}_{{C}_{1}} = \frac{{V}_{1}}{{R}_{1}} + {C}_{1} \frac{d {V}_{1}}{d t} ⇒ {\dot{V}}_{1} = \frac{- {V}_{1}}{{R}_{1} {C}_{1}} + \frac{I}{{C}_{1}}$$

where I represents the current, R₁ and R₂ are the polarization resistances, C₁ and C₂ are the polarization capacitances, V₁ shows the voltage drop due to the pair of charge-transfer polarization R₁ and polarization capacitance C₁. Similarly, the dynamics of the diffusion process is depicted as:

$$I = {I}_{{R}_{2}} + {I}_{{C}_{2}} = \frac{{V}_{2}}{{R}_{2}} + {C}_{2} \frac{d {V}_{2}}{d t} ⇒ {\dot{V}}_{2} = \frac{- {V}_{2}}{{R}_{2} {C}_{2}} + \frac{I}{{C}_{2}}$$

where V₂ represents the diffusion voltage modeled by the polarization capacitance C₂ and concentration polarization R₂. For a given time interval t, the variation in cell SOC is equal to the total charge stored or retrieved from the cell in that interval, the cell SOC can be expressed as follows:

$$s o c ( t ) = s o c ( 0 ) + Δ s o c = s o c ( 0 ) + {\int }_{0}^{t} \frac{η I ( τ )}{{C}_{t}} d τ ⇒ s \dot{o} c = \frac{η I}{{C}_{t}}$$

where η and Cₜ denote the coulombic efficiency and available cell capacity respectively. According to FIG. 1, the terminal voltage of the battery is expressed as:

$${V}_{o} = {V}_{o c} ( s o c ) + {V}_{1} + {V}_{2} + I {R}_{i n}$$

where Vₒ represents the terminal voltage, Rᵢₙ denotes the battery's internal resistance, V_{oc}(soc) represents the OCV source. Therefore, the battery ECM system can be presented by the set of the following state equations:

$$\{ \begin{matrix}\{ \begin{matrix}{\dot{V}}_{1} = - \frac{1}{{R}_{1} {C}_{1}} {V}_{1} + \frac{1}{{C}_{1}} I \\ {\dot{V}}_{2} = \frac{1}{{R}_{2} {C}_{2}} {V}_{2} + \frac{1}{{C}_{2}} I \\ s \dot{o} c = \frac{{η}_{i}}{{C}_{t}} I\end{matrix} \\ {V}_{o} = {V}_{o c} ( s o c ) + {V}_{1} + {V}_{2} + I {R}_{in}\end{matrix}$$

The above expression can be transformed into following form:

$$\{ \begin{matrix}\dot{x} = A x + Bu \\ y = h ( x ) + Du\end{matrix}$$

$$where$$

$$A = [ \begin{matrix}- 1 / {R}_{1} {C}_{1} & 0 & 0 \\ 0 & - 1 / {R}_{2} {C}_{2} & 0 \\ 0 & 0 & 0\end{matrix} ] , B = [ \begin{matrix}1 / {C}_{1} \\ 1 / {C}_{2} \\ η / {C}_{t}\end{matrix} ]$$

$$u = I , x = {[ {V}_{1} {V}_{2} soc ]}^{T} , D = {R}_{in}$$

$$h ( x ) = {V}_{o c} ( s o c ) + {V}_{1} + {V}_{2}$$

The internal states of above LIB system can be estimated using the following PI observer:

$$\{ \begin{matrix}\tilde{x} = A \tilde{x} + Bu + {K}_{p} ( y - \tilde{y} ) + {K}_{i} {S}_{e} \\ {\dot{S}}_{e} = {K}_{fi} ( y - \tilde{y} ) \\ \tilde{y} = h ( x ) + D u\end{matrix}$$

where Kₚ and Kᵢ are the proportional and integral gain matrices, respectively, Sₑ is the K_{fi} times integration of error.

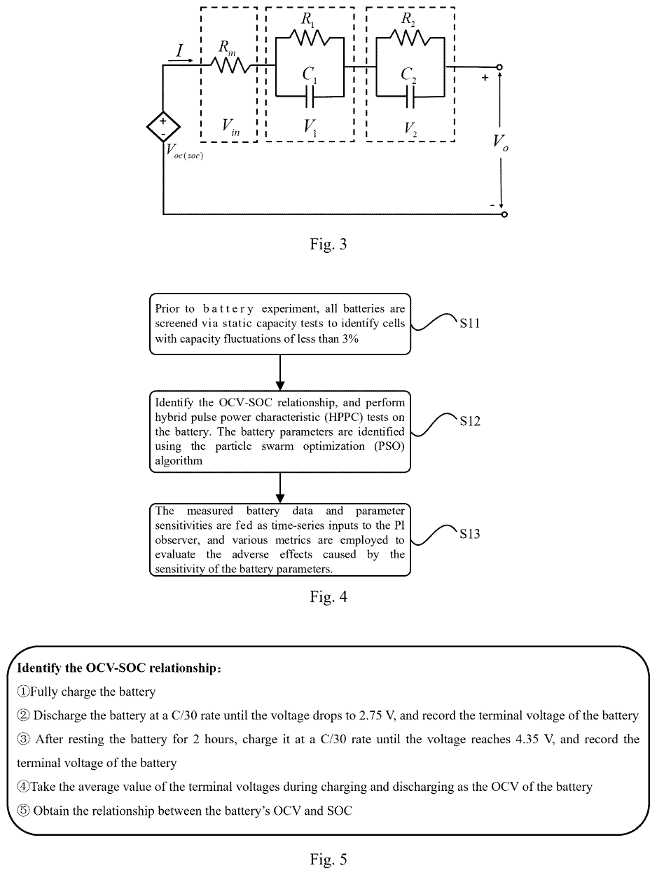

Referring to FIG. 4, the steps for performing parameter sensitivity analysis using the second-order RC ECM are as follows:

S11: Prior to battery experiment, all batteries are screened via static capacity tests to identify cells with capacity fluctuations of less than 3%.

S12: Identifying the OCV-SOC relationship. As shown in FIG. 5, the LIB is first charged using a constant current-constant voltage (CCCV) method at 0.25° C. until the charging current drops below 0.01C. These fully charged batteries are then discharged at a C/30 current rate until reaching Vₘᵢₙ (2.75V); After being rested for 2 hours, the batteries are charged with the same low current of C/30 till Vₘₐₓ (4.35V). As a very low discharge/charge current weakens the battery polarization and hysteresis effects to the greatest extent, the terminal voltage during charging V_{o,ch} can be expressed as:

$${V}_{o , ch} = {V}_{o c} ( s o c ) + {V}_{in} + I ( {R}_{1} + {R}_{2} )$$

Similarly, the terminal voltage Vₒ,dis during the discharge process can be expressed as:

$${V}_{o , dis} = {V}_{o c} ( s o c ) - {V}_{in} - I ( {R}_{1} + {R}_{2} )$$

By averaging the charging and discharging curves, the OCV of the LIB can be obtained:

$${V}_{o c} ( s o c ) = ( {V}_{o , ch} + {V}_{o , dis} ) / 2$$

After obtaining the OCV value at each point, the following relationship between SOC and OCV can be formulated between every two consecutive data points:

$${V}_{o c} ( soc ) = {m}_{i} \cdot soc + {c}_{i}$$

$$where$$

$${m}_{i} = \frac{{V}_{o {c}_{i + 1}} - {V}_{o {c}_{i}}}{s o {c}_{i + 1} - {soc}_{i}} , {c}_{i} = \frac{{V}_{o {c}_{i}} s o {c}_{i + 1} - {V}_{o {c}_{i + 1}} {soc}_{i}}{s o {c}_{i + 1} - {soc}_{i}}$$

After obtaining the OCV-SOC relationship, a series of hybrid pulse power characterization (HPPC) tests are performed on the battery. The key steps are as follows: (1) Fully charging the cell using the CCCV method at 0.25C until charging current falls below 0.01C; (2) Having a two-hour rest; (3) Discharging the cell at 0.1C for 5% and followed by a two-hour pause, repeated till the terminal voltage reaches Vₘᵢₙ; (4) Charging the cell at 0.1C for 5% and followed by a two-hour pause, repeated till the terminal voltage reaches Vₘₐₓ. The measured data is used for particle swarm optimization (PSO) algorithm to perform parameter identification.

S13: The measured battery data and parameter sensitivities are fed as time-series inputs to the PI observer. The adverse effects caused by parameter sensitivities are evaluated using metrics such as Maximum Absolute Error (MaxAE), Root Mean Square Error (RMSE), and Mean Absolute Error (MAE), which are expressed as follows:

$$\{ \begin{matrix}Max AE = max ( \vert {x}_{{o}_{i}} - {\hat{x}}_{{o}_{i}} \vert ) \\ RMSE = \sqrt{\frac{1}{N} {\sum }_{i = 1}^{N} {( {x}_{{o}_{i}} - {\hat{x}}_{{o}_{i}} )}^{2}} \\ MAE = \frac{1}{N} {\sum }_{i = 1}^{N} \vert {x}_{{o}_{i}} - {\hat{x}}_{{o}_{i}} \vert\end{matrix}$$

where xₒᵢ and \hat{x}ₒᵢ denote the measured and estimated state values, respectively.

S2: For the internal resistance, which serves as an uncertain dominant parameter, an appropriate extended PI observer is selected, wherein the internal resistance of the battery is transformed into an augmented state. The observer is then employed to realize the joint estimation of internal resistance and SOC; the selected PI observer is:

$$\{ \begin{matrix}\tilde{x} = A \tilde{x} + B u + {K}_{p} ( y - \tilde{y} ) + {K}_{i} {S}_{e} \\ {\dot{S}}_{e} = {K}_{f i} ( y - \tilde{y} ) \\ \tilde{y} = h ( x ) + D u\end{matrix}$$

where Kₚ and Kᵢ are the proportional and integral gain matrices, respectively, Sₑ is the K_{fi} times integration of error.

S3: An intelligent strategy based on information fusion and fuzzy logic is established to enable real-time detection of model deficiencies. The strategy is integrated with the extended PI observer and employs an improved LOD concept combined with knowledge-based fuzzy logic to detect model uncertainty in real time. According to a set of predefined rules, the control logic is adaptively adjusted to regulate the internal polarization behavior of the battery, thereby providing timely compensation for modeling defects and ensuring the accuracy of state and parameter estimation.

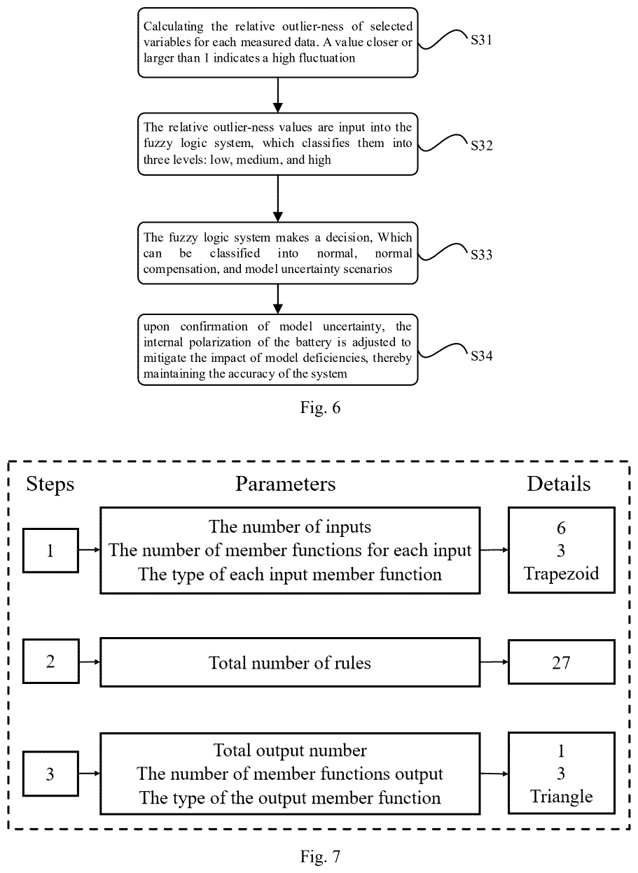

Referring to FIG. 6 and FIG. 7, the steps for effectively detecting model uncertainty using an intelligent strategy based on information fusion and fuzzy logic are as follows:

S31: Calculating the relative outlier-ness of selected variables for each measured data. A value closer or larger than 1 indicates a high fluctuation. The relative outlier-ness is calculated as follows:

$$\text{?} {x}_{k} = d ( {x}_{k} , {x}_{k - 1} ) / abs ( {x}_{k} )$$

S32: The relative outlier-ness values are input into the fuzzy logic system, which classifies them into three levels: low, medium, and high. In addition, the input describing the current system state (i.e., whether the system has returned to normal and accumulated error returns to its previous value) is also fed back into the fuzzy system. The fuzzy logic process comprises three steps: fuzzification, rule formulation, and defuzzification. The fuzzy logic model defines a total of 27 rules, in the form of IF THEN conditions, and has been verified through sufficient experimentation.

S33: The fuzzy logic system makes a decision, which can be classified into normal, normal compensation, and model uncertainty scenarios.

S34: Compensating model defects. Whenever the model output eₖ exhibits fluctuations exceeding a predetermined threshold, its score is observed, and similar trends are searched among the scores of sôcₖ [symbol] Icrₖ and dVocₖ₋₁. Upon the confirmation of model uncertainty, the proposed method is employed to adjust the internal polarization of the battery to mitigate the effects of modeling defects and maintain system accuracy, until the system returns to a normal state and the cumulative error recovers to its previous value. Where the extended PI Observer can be depicted using the following expressions:

$$\{ \begin{matrix}{\hat{x}}_{e o} = {A}_{e o} {\hat{x}}_{e o} + {B}_{e o} u + {K}_{{p}_{eo}} ( y - \hat{y} ) + {K}_{i {2}_{eo}} {S}_{e} \\ {\dot{S}}_{e} = {K}_{i {1}_{eo}} ( y - \hat{y} ) \\ \hat{y} = {h}_{e o} ( {\hat{x}}_{e o} , u )\end{matrix}$$

$$where$$

$${x}_{e o} = {[ {V}_{1} {V}_{2} soc {R}_{in} ]}^{T}$$

$${A}_{e o} = [ \begin{matrix}- 1 / {R}_{1} {C}_{1} & 0 & 0 & 0 \\ 0 & - 1 / {R}_{2} {C}_{2} & 0 & 0 \\ 0 & 0 & 0 & 0 \\ 0 & 0 & 0 & 0\end{matrix} ] ; {B}_{e o} = [ \begin{matrix}1 / {C}_{1} \\ 1 / {C}_{2} \\ {η}_{i} / {C}_{t} \\ 0\end{matrix} ]$$

$${h}_{e o} ( {\hat{x}}_{e o} , u ) = {V}_{o c} ( s \hat{o} c ) + {\hat{V}}_{1} + {\hat{V}}_{2} + {\hat{R}}_{in} I$$

$${K}_{{p}_{eo}} = {[ {K}_{p {1}_{eo}} {K}_{p {2}_{eo}} {K}_{p {3}_{eo}} {K}_{p {4}_{eo}} ]}^{T}$$

$${K}_{{i}_{eo}} = {[ {K}_{i {1}_{eo}} {K}_{i {2}_{eo}} {K}_{i {3}_{eo}} {K}_{i {4}_{eo}} ]}^{T}$$

where Kₚₑₒ and Kᵢₑₒ are proportional and integral gain matrices functions, respectively. Moreover, the output hₑₒ(\hat{x}ₑₒ, u) for this design is not a linear function at all in the terms of u.

S4: The observability of the proposed method is verified, and experimental validation is conducted to evaluate the practicality of the method under various random operating conditions.

The observability verification method described in Step S4 is as follows: for a nonlinear system, determining the system's observability using the Lie derivative theorem. Based on the Lie derivatives, the battery system can be represented as:

$$\{ \begin{matrix}{\dot{x}}_{e o} = {A}_{e o} x + {B}_{e o} u \\ y = {h}_{e o} ( {x}_{e o} , u )\end{matrix}$$

If the gradient matrix of the Lie derivatives is fully-ranked or has independent rows, the system is observable at any point

$${x}_{e o}^{0} .$$

$$O = {[ d {h}_{e o} {dL}_{{A}_{e o} {x}_{e o}}^{1} h {dL}_{{B}_{e o}}^{1} h {dL}_{{A}_{e o} {x}_{e o}}^{2} h {dL}_{{B}_{e o}}^{2} h … ]}^{T}$$

$$where$$

$$d {h}_{e o} = \partial {h}_{e o} / \partial {x}_{e o} = [ \partial {h}_{e o} / \partial {x}_{e {o}_{1}} \partial {h}_{e o} / \partial {x}_{e {o}_{2}} … \partial {h}_{e o} / \partial {x}_{e {o}_{n}} ]$$

$${L}_{{A}_{{eo}^{x} eo}} {h}_{e o} ( {x}_{e o} ) = [ \partial {h}_{e o} / \partial {x}_{e {o}_{1}} \partial {h}_{e o} / \partial {x}_{e {o}_{2}} … \partial {h}_{e o} / \partial {x}_{e {o}_{n}} ] \cdot {A}_{e o} {x}_{e o}$$

$${L}_{{B}_{eo}} {h}_{e o} ( {x}_{e o} ) = \partial {h}_{e o} / \partial {x}_{e {o}_{1}} \partial {h}_{e o} / \partial {x}_{e {o}_{2}} … \partial {h}_{e o} / \partial {x}_{e {o}_{n}} \cdot {B}_{e o}$$

$${L}_{{A}_{e o} {x}_{e o}}^{k} {h}_{e o} ( {x}_{e o} ) = {L}_{{A}_{e o} {x}_{e o}} ( {L}_{{A}_{e o} {x}_{e o}}^{k - 1} {h}_{e o} ( {x}_{e o} ) ) ; {L}_{{B}_{e o}}^{k} {h}_{e o} ( {x}_{e o} ) = {L}_{{B}_{e o}} ( {L}_{{B}_{e o}}^{k - 1} {h}_{e o} ( {x}_{e o} ) )$$

based on

$${x}_{e o} = {[ {V}_{l} , {V}_{2} , soc {R}_{in} ]}^{T}$$

$$u = I , y = {V}_{o}$$

$${A}_{e o} {x}_{e o} = {[ - {V}_{l} / {R}_{f} {C}_{f} {V}_{2} / {R}_{2} {C}_{2} 00 ]}^{T}$$

$${B}_{e o} = {[ 1 / {C}_{f} 1 / {C}_{2} {η}_{i} / {C}_{t} 0 ]}^{T}$$

$$h ( {x}_{e o} , u ) = {V}_{o c} ( s o c ) + {V}_{l} + {V}_{2} + {R}_{in} u$$

The gradient of the Lie derivatives is calculated as follows:

$$d {h}_{e o} = [ 11 {dV}_{oc} / dsoc I ]$$

$${L}_{{A}_{e o} {x}_{e o}}^{k} {h}_{e o} ( {x}_{e o} ) = [ 1 / {( - {R}_{1} {C}_{1} )}^{k} 1 / {( - {R}_{2} {C}_{2} )}^{k} 00 ]$$

$${L}_{{B}_{e o}}^{k} {h}_{e o} ( {x}_{e o} ) = [ 00 {( {η}_{i} / {C}_{t} )}^{k} \cdot {d}^{k + 1} {∇}_{oc} / {dsoc}^{k + 1} 0 ]$$

The observability matrix is given as follows:

$$[ \begin{matrix}d {h}_{e o} \\ {dL}_{{A}_{eo} {x}_{eo}} {}^{1} h \\ {dL}_{{B}_{eo}} {}^{1} h \\ {dL}_{{A}_{eo} {x}_{eo}} {}^{2} h \\ {dL}_{{B}_{eo}} {}^{2} h \\ {dL}_{{h}_{o} {x}_{eo}} {}^{k} h \\ {dL}_{{B}_{eo}} {}^{k} h\end{matrix} ] = [ \begin{matrix}1 & 1 & {dV}_{oc} / dsoc & I \\ \frac{1}{- {R}_{1} {C}_{1}} & \frac{1}{- {R}_{2} {C}_{2}} & 0 & 0 \\ 0 & 0 & \frac{{η}_{i}}{{C}_{t}} ▯ \frac{{d}^{2} {V}_{oc}}{{dsoc}^{2}} & 0 \\ \frac{1}{{( - {R}_{1} {C}_{1} )}^{2}} & \frac{1}{{( - {R}_{2} {C}_{2} )}^{2}} & 0 & 0 \\ 0 & 0 & {( \frac{{η}_{i}}{{C}_{t}} )}^{2} ▯ \frac{{d}^{3} {V}_{oc}}{{dsoc}^{3}} & 0 \\ \frac{1}{{( - {R}_{1} {C}_{1} )}^{k}} & \frac{1}{{( - {R}_{2} {C}_{2} )}^{k}} & 0 & 0 \\ 0 & 0 & {( \frac{{η}_{i}}{{C}_{t}} )}^{k} ▯ \frac{{d}^{k + 1} {V}_{oc}}{{dsoc}^{k + 1}} & 0\end{matrix} ]$$

When d^{k}V_{oc}/dsoc^{k}≠0 and I≠0, the above matrix is fully ranked. As the OCV is a complex nonlinear function of battery SOC, the first condition will be hold constantly. However, the unobservability when I=0 can be physically understood by the fact that in such case the augmented state will be multiplied by the zero and its effect will not even be reflected in the output voltage. So, it is necessary to set [Kₚ₄ₑₒ;Kᵢ₄ₑₒ] to zero when I=0 to avoid misleading results.

In the above embodiments, references to “the present embodiment” indicate that specific features, structures, or characteristics described in connection with the embodiment are included in at least some, but not necessarily all, embodiments. The multiple occurrences of the phrase “the present embodiment” do not necessarily refer to the same embodiment.

In the above embodiments, although the present invention has been described with reference to specific embodiments, it will be apparent to those of ordinary skill in the art that many substitutions, modifications, and variations of these embodiments are possible in light of the foregoing description. For example, other storage structures (such as dynamic RAM (DRAM)) may be used in the discussed embodiments. The embodiments of the present invention are intended to cover all such substitutions, modifications, and variations that fall within the broad scope of the appended claims.

The present embodiment further provides a computer-readable storage medium on which a computer program is stored, and when executed by a processor, the program implements any one of the methods described in the present embodiment.

The present embodiment further provides an electronic terminal, comprising: a processor and a memory;

The memory is configured to store a computer program, and the processor is configured to execute the computer program stored in the memory so as to enable the terminal to perform any one of the methods described in the present embodiment.

For the computer-readable storage medium in the present embodiment, it can be understood by those of ordinary skill in the art that all or part of the steps of the above-mentioned method embodiments may be implemented by hardware related to a computer program. The aforementioned computer program may be stored in a computer-readable storage medium. When executed, the program performs the steps included in the method embodiments described above. The storage medium may include various media capable of storing program code, such as ROM, RAM, magnetic disks, or optical disks.

The electronic terminal provided in the present embodiment includes a processor, a memory, a transceiver, and a communication interface. The memory and the communication interface are connected to the processor and the transceiver to enable communication therebetween. The memory is configured to store a computer program, the communication interface is configured to perform communication, and the processor and the transceiver are configured to run the computer program so as to cause the electronic terminal to execute the steps of the above method.

In the present embodiment, the memory may include a random access memory (RAM) and may further include a non-volatile memory, such as at least one disk storage device.

The above-mentioned processor may be a general-purpose processor, including a Central Processing Unit (CPU), a Network Processor (NP), and the like. It may also be a Digital Signal Processor (DSP), an Application Specific Integrated Circuit (ASIC), a Field-Programmable Gate Array (FPGA), or other programmable logic devices, discrete gate or transistor logic devices, or discrete hardware components.

The present invention may be applied in numerous general-purpose or specialized computing system environments or configurations. Examples include personal computers, server computers, handheld or portable devices, tablet devices, multiprocessor systems, microprocessor-based systems, set-top boxes, programmable consumer electronics, network PCs, minicomputers, mainframe computers, and distributed computing environments that include any of the above systems or devices.

The present invention may be described in the general context of computer-executable instructions executed by a computer, such as program modules. Generally, program modules include routines, programs, objects, components, data structures, and the like that perform particular tasks or implement particular abstract data types. The present invention may also be practiced in distributed computing environments, where tasks are performed by remote processing devices that are linked through a communication network. In such distributed computing environments, program modules may be located in both local and remote computer storage media, including storage devices.

It should be noted that the above embodiments are intended to illustrate, rather than limit, the technical solutions of the present invention. Although the present invention has been described in detail with reference to the preferred embodiments, those of ordinary skill in the art should understand that modifications or equivalent substitutions can be made to the technical solutions of the present invention without departing from the spirit and scope thereof, and all such modifications or substitutions shall fall within the scope of the claims of the present invention.

1. A method for the joint estimation of internal resistance and SOC of a lithium-ion battery based on a fuzzy-empowered PI observer, the method comprising:
S1: designing an appropriate extended PI observer to transform a battery internal resistance into an augmented state, so as to jointly estimate the internal resistance and SOC;
wherein in step S1, the extended PI observer is as follows:
$$\{ \begin{matrix}\dot{\tilde{x}} = A \tilde{x} + Bu + {K}_{p} ( y - \tilde{y} ) + {K}_{i} {S}_{e} \\ {\dot{S}}_{e} = {K}_{fi} ( y - \tilde{y} ) \\ \tilde{y} = h ( x ) + D u\end{matrix}$$
$$where$$
$$A = [ \begin{matrix}- 1 / {R}_{1} {C}_{1} & 0 & 0 \\ 0 & - 1 / {R}_{2} {C}_{2} & 0 \\ 0 & 0 & 0\end{matrix} ] , B = [ \begin{matrix}1 / {C}_{1} \\ 1 / {C}_{2} \\ η / {C}_{t}\end{matrix} ] ;$$
$$u = I , x = {[ {V}_{1} {V}_{2} soc ]}^{T} , D = {R}_{in}$$
$$h ( x ) = {V}_{o c} ( s o c ) + {V}_{1} + {V}_{2}$$
Kₚ and Kᵢ are proportional and integral gain matrices; Sₑ is a cumulative error;
S2: developing an intelligent strategy empowered by an information fusion and a fuzzy logic, wherein, based on the extended PI observer, employing a concept of low density outlier detection (LOD) in combination with the knowledge-based fuzzy logic to detect model uncertainty in real time;
wherein step S2 further comprises the following steps:
S21: calculating a relative outlier-ness of selected variables for each measured data; a value closer or greater than 1 indicating a high fluctuation;
S22: the relative outlier-ness values being input into a fuzzy logic system configured to classify them into three levels: low, medium, and high; an input describing a current system state is also fed back into the fuzzy system;
S23: the fuzzy logic system making a decision classified into normal, normal compensation, and model uncertainty scenarios;
wherein in step S2, the extended PI observer is described by the following expression:
$$\{ \begin{matrix}{\dot{\hat{x}}}_{e o} = {A}_{eo} {\hat{x}}_{e o} + {B}_{eo} u + {K}_{{p}_{eo}} ( y - \hat{y} ) + {K}_{i {2}_{e o}} {S}_{e} \\ {\dot{S}}_{e} = {K}_{i {1}_{eo}} ( y - \hat{y} ) \\ \hat{y} = {h}_{e o} ( {\hat{x}}_{e o} , u )\end{matrix}$$
where
xₑₒ=[V₁ V₂ soc Rᵢₙ]^{T};
V₁ is the voltage drop due to the pair of charge-transfer polarization R₁ and polarization capacitance C₁; V₂ represents the diffusion voltage modeled by the polarization capacitance C₂ and concentration polarization R₂; soc is the cell SOC; Rᵢₙ denotes the battery's internal resistance;
$${A}_{e o} = [ \begin{matrix}- 1 / {R}_{1} & {C}_{1} & 0 & 0 & 0 \\ 0 & & - 1 / {R}_{2} {C}_{2} & 0 & 0 \\ ( ) & & 0 & 0 & 0 \\ 0 & & 0 & 0 & 0\end{matrix} ] ; {B}_{e o} = [ \begin{matrix}1 / {C}_{1} \\ 1 / {C}_{2} \\ {η}_{i} / {C}_{t} \\ 0\end{matrix} ]$$
$${h}_{e o} ( {\hat{x}}_{e o} , u ) = {V}_{o c} ( s ô c ) + {\hat{V}}_{1} + {\hat{V}}_{2} + {\hat{R}}_{in} I$$
$${K}_{{p}_{eo}} = {[ {K}_{p {1}_{e o}} {K}_{p {2}_{eo}} {K}_{p {3}_{e o}} {K}_{p {4}_{e o}} ]}^{T}$$
$${K}_{{i}_{e o}} = {[ {K}_{i {1}_{eo}} {K}_{i {2}_{eo}} {K}_{i {3}_{eo}} {K}_{i {4}_{eo}} ]}^{T}$$
where R₁ and R₂ are the polarization resistances; C₁ and C₂ are the polarization capacitances; Kₚₑₒ and Kᵢₑₒ are the proportional and integral gain matrices, respectively.
S3: according to predefined rules, modifying a control logic and adjusting an internal polarization of the battery to achieve timely compensation for modeling deviations, thereby ensuring accurate SOC estimation.

2. The method of claim 1, wherein in step S22, the fuzzy logic process comprises three steps: fuzzification, rule formulation, and defuzzification; a fuzzy logic model defining a set of rules, each fuzzy rule being expressed in a form of an IF-THEN condition.
